(19) United States
(12) Patent Application Publication
(10) Pub. No.: US 2007/0218316 A1
(43) Pub. Date: Sep. 20, 2007

(54) Magnetic recording medium, method of producing same, and magnetic storage apparatus

(75) Inventor: Akihiro Inomata, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/474,402

(22) Filed: Jun. 26, 2006

(30) Foreign Application Priority Data
Mar. 20, 2006 (JP) 2006-076775

(51) Int. Cl. G11B 5/66; C23C 14/00

(52) U.S. Cl. 428/828; 428/831.2; 428/836.2; 428/836.3; 360/131; 204/192.2

(57) ABSTRACT

A magnetic recording medium according to one aspect of the present invention includes a substrate; an underlayer positioned on the substrate and made of a material having a body-centered-cubic crystalline structure or a B2 crystalline structure; a first intermediate layer positioned on the underlayer and having a hexagonal closest packing crystalline structure, and being made of Co or a Co alloy; a second intermediate layer positioned on the first intermediate layer and having a hexagonal closest packing crystalline structure, and being made of a material selected from the group consisting of Ru, Ti, Re, Zr, Hf, and a Ru alloy; and a magnetic layer positioned on the second intermediate layer and including multiple magnetic grains each having a hexagonal closest packing crystalline structure and an axis of easy magnetization oriented in a direction substantially parallel to a surface of the substrate, wherein the magnetic grains are isolated from each other.

### CROSS-REFERENCE TO RELATED APPLICATIONS

The present application is based upon and claims the benefit of priority from the prior Japanese Patent Application No. 2006-076775 filed on Mar. 20, 2006, with the Japanese Patent Office, the entire contents of which are incorporated herein by reference.

### BACKGROUND OF THE INVENTION

1. Field of the Invention

The present invention generally relates to a magnetic recording medium, a method of producing a magnetic recording medium, and a magnetic storage apparatus, and more particularly relates to a magnetic recording medium, a method of producing a magnetic recording medium, and a magnetic storage apparatus which are implemented by using a longitudinal magnetic recording method.

2. Description of the Related Art

The market demand for a magnetic storage apparatus with higher capacity is very high. Combined with a demand for a smaller magnetic storage apparatus, implementation of a very high density recording technology is looked forward to. The perpendicular magnetic recording method is said to be theoretically able to provide higher density than the longitudinal magnetic recording method which is the current mainstream of magnetic recording methods. The commercial production of magnetic storage apparatuses using the perpendicular magnetic recording method has already been started. However, because of concern about their reliability and high production costs, there is still a substantial risk in starting a full-scale mass production of such magnetic storage apparatuses. For this reason, the market demand for improved magnetic recording density using the longitudinal magnetic recording method is also high.

The reasons making it hard to improve the recording density of a magnetic recording medium using the longitudinal magnetic recording method include the difficulty in maintaining sufficient recordability and in improving the signal-to-noise (S/N) ratio of a magnetic recording medium having an alloy recording layer using an alloy such as a CoCrPtB alloy. Poor recordability may result from the lack of sufficient recording head magnetic field. In other words, it is very difficult to make the switching magnetic field of magnetic grains comprising a recording layer smaller than the recording head magnetic field.

The switching magnetic field is approximately proportional to the anisotropy field Hk of magnetic grains. The anisotropy field Hk is obtained by using a formula Hk=2 Ku/Ms. In this formula, Ku is the magnetocrystalline anisotropy constant and Ms is the saturation magnetization of a recording layer. The S/N ratio of a magnetic recording medium can be improved by reducing the size of magnetic grains. However, as the magnetic grain size decreases, the rate of decrease over time in remanent magnetization caused by thermal disturbance increases. As a countermeasure to this problem, the magnetocrystalline anisotropy constant Ku may be increased.

Further, from the aspect of materials for alloy recording layers, it is preferable to increase the content of a non-magnetic material in an alloy recording layer to reduce the magnetic grain diameter and to segregate the non-magnetic material. However, since the saturation magnetization Ms in the core of each magnetic grain decreases, the anisotropy field Hk increases according to the above formula. As a consequence, in a magnetic recording medium using an alloy recording layer, the switching magnetic field increases as the recording density increases, and maintaining recordability becomes difficult.

As another type of magnetic recording medium, a granular medium has been proposed (for example, such as that shown in patent document 1). A granular medium has a recording layer in which magnetic grains grown in a non-magnetic base material in a direction perpendicular to the substrate surface are distributed in a direction parallel to the substrate surface. In a granular medium, magnetic grains in the recording layer are isolated from each other by a non-magnetic base material. Since magnetic grains and the non-magnetic base material do not dissolve in each other, the composition of magnetic grains can be easily controlled. In other words, unlike in a conventional alloy recording layer, there is no need to increase the content of non-magnetic material in a magnetic grain to reduce its grain diameter and to segregate the non-magnetic material. Therefore, increase in the switching magnetic field Ho resulting from decrease in the saturation magnetization Ms can be avoided. A granular medium makes it possible to reduce the medium noise while maintaining the saturation magnetization, thereby providing a magnetic recording medium with an excellent S/N ratio.

[Patent document 1] Japanese Patent Application Publication No. 2001-56922

However, with a conventional granular medium, it is difficult to achieve a sufficient in-plane coercivity (coercivity in a direction parallel to the substrate surface) and a sufficient in-plane orientation (a degree to which the axis of easy magnetization of a magnetic grain is oriented in a direction parallel to the substrate surface) at the same time. For this reason, further improving the recording density of a granular medium is difficult.

### SUMMARY OF THE INVENTION

The present invention provides a magnetic recording medium, a method of producing a magnetic recording medium, and a magnetic storage apparatus that substantially obviate one or more problems caused by the limitations and disadvantages of the related art. Preferred embodiments of the present invention may particularly provide a magnetic recording medium having a high coercivity and an excellent in-plane orientation, a method of producing such a magnetic recording medium, and a magnetic storage apparatus having such a magnetic recording medium.

According to one aspect of the present invention, a magnetic recording medium includes a substrate; an underlayer positioned on the substrate and made of a material having a body-centered-cubic crystalline structure or a B2 crystalline structure; a first intermediate layer positioned on the underlayer and having a hexagonal closest packing crystalline structure, and being made of Co or a Co alloy; a second intermediate layer positioned on the first intermediate layer and having a hexagonal closest packing crystalline structure, and being made of a material selected from the group consisting of Ru, Ti, Re, Zr, Hf, and a Ru alloy; and a magnetic layer positioned on the second intermediate layer and including multiple magnetic grains each having a hexagonal closest packing crystalline structure and an axis of easy magnetization oriented in a direction substantially parallel to a surface of the substrate, wherein the magnetic grains are isolated from each other.

According to one aspect of the present invention, a magnetic recording medium includes an underlayer made of a material having a body-centered-cubic crystalline structure or a B2 crystalline structure, and serving as a base for a magnetic layer having a granular structure; a first intermediate layer having a hexagonal closest packing crystalline structure and made of Co or a Co alloy; a second intermediate layer having a hexagonal closest packing crystalline structure and made of a material selected from the group consisting of Ru, Ti, Re, Zr, Hf, and a Ru alloy. This configuration improves the in-plane orientation of the c axis of each magnetic grain having a hexagonal closest packing crystalline structure and improves the in-plane coercivity. As a result, a magnetic recording medium according to an embodiment of the present invention provides an excellent S/N ratio which is a feature of a magnetic layer having a granular structure. Such a magnetic recording medium provides an improved in-plane coercivity and in-plane orientation. The present invention makes it possible to provide a magnetic recording medium with an improved recording density. In this specification, an in-plane coercivity is a coercivity in a direction parallel to the surface of a substrate; and an in-plane orientation is a degree to which the c axis (axis of easy magnetization) of a magnetic grain is oriented in a direction parallel to the substrate surface.

According to another aspect of the present invention, a method of producing a magnetic recording medium includes an underlayer forming step of forming on a substrate an underlayer by depositing a material having a body-centered-cubic crystalline structure or a B2 crystalline structure; a first intermediate layer forming step of forming on the underlayer a first intermediate layer having a hexagonal closest packing crystalline structure by depositing a material composed of Co or a Co alloy; a second intermediate layer forming step of forming on the first intermediate layer a second intermediate layer having a hexagonal closest packing crystalline structure by depositing a material selected from the group consisting of Ru, Ti, Re, Zr, Hf, and a Ru alloy; and a magnetic layer forming step of forming on the second intermediate layer a magnetic layer by sputtering simultaneously a ferromagnetic material and a non-magnetic material which does not dissolve the ferromagnetic material or dissolve in the ferromagnetic material and is composed of an oxide, a nitride, or a carbide.

A magnetic recording medium according to an embodiment of the present invention provides an excellent S/N ratio which is a feature of a magnetic layer having a granular structure. Such a magnetic recording medium provides an improved in-plane coercivity and in-plane orientation.

According to still another aspect of the present invention, a magnetic storage apparatus includes a record reproducing unit having a magnetic head; and a magnetic recording medium according to an embodiment of the present invention.

A magnetic recording medium according to an embodiment of the present invention provides an excellent S/N ratio, in-plane coercivity, and in-plane orientation. Such a magnetic recording medium enables production of a magnetic storage apparatus having a high recording density.

According to one aspect of the present invention, a magnetic recording medium includes an underlayer, as a base for a magnetic layer having a granular structure, made of a material having a body-centered-cubic crystalline structure or a B2 crystalline structure; a first intermediate layer having a hexagonal closest packing crystalline structure and made of Co or a Co alloy; a second intermediate layer having a hexagonal closest packing crystalline structure and made of a material selected from the group consisting of Ru, Ti, Re, Zr, Hf, and a Ru alloy. This configuration enables providing a magnetic recording medium having a high recording density. The present invention provides such a magnetic recording medium, a method of producing such a magnetic recording medium, and a magnetic storage medium having such a magnetic recording medium.

### BRIEF DESCRIPTION OF THE DRAWINGS

FIG. 1 is a cross-sectional view of a first exemplary magnetic recording medium according to a first embodiment of the present invention;

FIG. 2 is a cross-sectional view of a second exemplary magnetic recording medium according to the first embodiment of the present invention;

FIG. 3 is a cross-sectional view of a third exemplary magnetic recording medium according to the first embodiment of the present invention;

FIG. 4 is a cross-sectional view of a fourth exemplary magnetic recording medium according to the first embodiment of the present invention;

FIG. 5 is a table showing exemplary layer configurations and magnetic properties of magnetic disks in example 1 and comparative example 1;

FIG. 6 is a table showing exemplary layer configurations and magnetic properties of magnetic disks in example 2 and comparative example 2;

FIG. 7A is a graph showing a relationship between in-plane coercivities and magnetic layer thicknesses of magnetic disks in examples 3 and 4;

FIG. 7B is a graph showing a relationship between coercivity ratios and magnetic layer thicknesses of magnetic disks in examples 3 and 4;

FIG. 8A is a graph showing a relationship between in-plane coercivities and Co film thicknesses of a magnetic disk in example 5;

FIG. 8B is a graph showing a relationship between coercivity ratios and Co film thicknesses of a magnetic disk in example 5;

FIG. 9A is a graph showing a relationship between in-plane coercivities and Ru film thicknesses of a magnetic disk in example 6;

FIG. 9B is a graph showing a relationship between coercivity ratios and Ru film thicknesses of a magnetic disk in example 6;

FIG. 10A is a graph showing a relationship between in-plane coercivities and CO₉₀Cr₁₀ film thicknesses of a magnetic disk in example 7;

FIG. 10B is a graph showing a relationship between coercivity ratios and CO₉₀Cr₁₀ film thicknesses of a magnetic disk in example 7;

FIG. 11 is a graph showing a relationship between in-plane coercivities and magnetic layer thicknesses of magnetic disks in examples 8 and 9; and

FIG. 12 is a drawing showing a portion of an exemplary magnetic storage apparatus according to a second embodiment of the present invention.

### DETAILED DESCRIPTION OF THE PREFERRED EMBODIMENTS

Preferred embodiments of the present invention are described below with reference to accompanying drawings.

### 1. First Embodiment

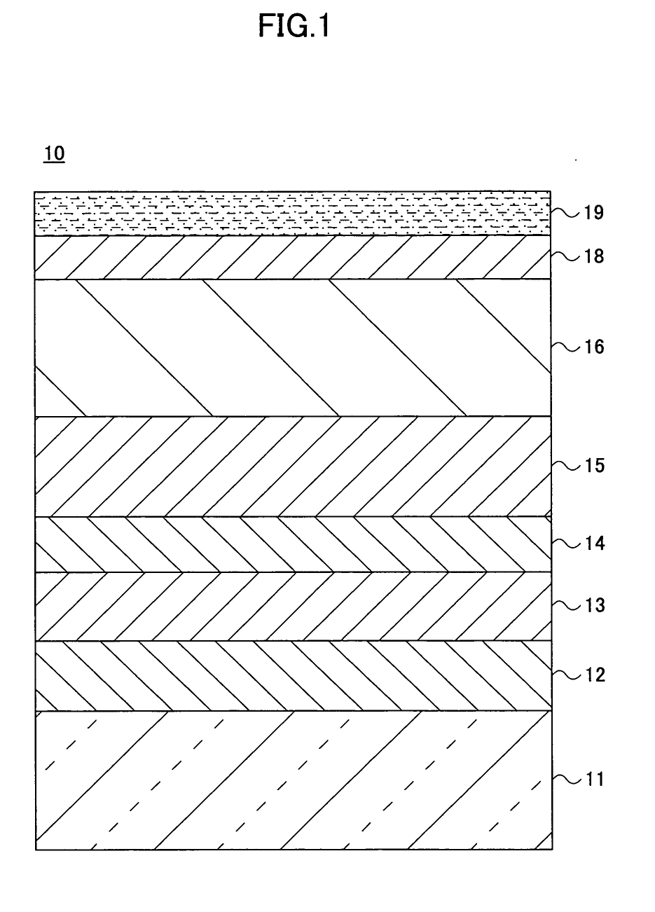

FIG. 1 is a cross-sectional view of a first exemplary magnetic recording medium according to the first embodiment of the present invention. As shown in FIG. 1, a first exemplary magnetic recording medium 10 has a structure in which a substrate 11, a seed layer 12, an underlayer 13, a first intermediate layer 14, a second intermediate layer 15, a magnetic layer 16, a protective film 18, and a lubrication layer 19 are disposed from bottom to top in the order mentioned.

For the substrate 11, materials including, for example, glass, NiP-plated aluminum alloy, silicon, plastic, ceramic, carbon may be used.

The surface of the substrate 11 may have a texture (a mechanical texture, for example) made up of multiple grooves along the recording direction (for example, the circumferential direction when the magnetic recording medium 10 is a magnetic disk). Such a texture assists orienting the c axis (axis of easy magnetization) of the magnetic layer 16 in the recording direction. This results in an improvement in magnetic properties of the magnetic recording medium 10 and further results in an improvement in recording/reproducing characteristics such as reproduction output and resolution. The texture may be formed on the surface of the seed layer 12 described below instead of on the surface of the substrate 11.

The seed layer 12 is made of a non-magnetic alloy material in an amorphous state. The material for the seed layer 12 is preferably CoW, CrTi, NiP, or an alloy containing any one of these alloys as a primary component and composed of three or more metal elements. Such alloys enable reducing the diameter of each crystal grain in the underlayer 13. Also, the thickness of the seed layer 12 is preferably within a range between 5 nm and 100 nm. Since the seed layer 12 is in an amorphous state, its surface is crystallographically uniform. Therefore, forming the underlayer 13 on this seed layer 12 can better prevent the underlayer 13 from having crystallographical anisotropy than forming the underlayer 13 directly on the substrate surface. The seed layer 12 thus makes it easier for the underlayer 13 to form its own crystalline structure and improves the crystallinity and crystal orientation. This in turn improves the crystallinity and crystal orientation of the first intermediate layer 14, the second intermediate layer 15, and the magnetic layer 16 which grow epitaxially on the underlayer 13. Further, the in-plane orientation and in-plane coercivity of the c axis of each magnetic grain in the magnetic layer 16 improve and, as a result, the recording/reproducing characteristics improve.

Also, with the seed layer 12 in an amorphous state, the diameter of each crystal grain in the underlayer 13 can be reduced and dispersion of the diameters of crystal grains can be minimized. This reduces the diameter of each magnetic grain in the magnetic layer 16 and minimizes dispersion of the diameters of the magnetic grains, thereby improving the signal-to-noise (S/N) ratio. As described above, it is preferable to have the seed layer 12 in a magnetic recording medium, but it is not essential.

The underlayer 13 is made of a material having a body-centered-cubic crystalline structure or a B2 crystalline structure. The underlayer 13 is preferably made of Cr, W, Mo, V, or a Cr-X1 alloy each having a body-centered-cubic crystalline structure (X1 is selected from the group consisting of Mo, W, V, B, Mn, and Ti).

The material having a B2 crystalline structure for the underlayer 13 is preferably AlCo, AlMn, AlRe, AlRu, AgMg, CuBe, CuZn, CoFe, CoHf, CoTi, CoZr, FeAl, FeTi, NiAl, NiFe, NiTi, AlRuNi, or Al₂FeMn₂. The underlayer 13 orients the c axis of the first intermediate layer 14 and the second intermediate layer 15, which have a hexagonal closest packing crystalline structure, in a direction parallel to the substrate surface. This in turn orients the c axis of the magnetic layer 16, which is on the second intermediate layer 15, in a direction parallel to the substrate surface, thereby improving the in-plane orientation of the c axis. Hereafter, “the c axis of each magnetic grain in the magnetic layer 16” is just called “the c axis of the magnetic layer 16” unless otherwise stated.

Also, the underlayer 13 is preferably an AlRu film. Using an AlRu film as the underlayer 13 and depositing the first intermediate layer 14 and the second intermediate layer 15 on the underlayer 13 provides an excellent in-plane orientation of the c axis of the magnetic layer 16.

Although there is no particular limit, the thickness of the underlayer 13 is preferably greater than or equal to 3 nm to sufficiently improve the in-plane orientation of the magnetic layer 16. Also, to prevent magnetic grains in the magnetic layer 16 from growing too big, the thickness of the underlayer 13 is preferably less than or equal to 30 nm.

The first intermediate layer 14 is made of Co or a Co alloy having a hexagonal closest packing crystalline structure. The Co alloy for the first intermediate layer 14 is preferably Co-X2 (X2 is selected from the group consisting of Cr, Ta, Mo, Mn, Re, and Ru). The first intermediate layer 14 further improves the in-plane orientation of the c axis of the magnetic layer 16. In other words, the first intermediate layer 14 multiplies the effect of the underlayer 13 of improving the in-plane orientation, thereby further improving the in-plane orientation of the c axis of the magnetic layer 16.

When a texture is formed on the substrate 11 or the seed layer 12, the effect of the texture is combined with the effects of the underlayer 13 and the first intermediate layer 14, and provides an excellent in-plane orientation, in the recording direction, of the c axis of the magnetic layer 16.

The first intermediate layer 14 is preferably made of Co (pure Co), or CoCr or a CoCr alloy (CoCr-X3 [X3 is selected from the group consisting of Ta, Mo, Mn, Re, and Ru]) each containing Co as its primary component (Co content is greater than or equal to 63 atomic percent and less than 100 atomic percent). If the Co content is less than 63 atomic percent, the in-plane orientation of the c axis of the magnetic layer 16 may deteriorate. As the Co content in CoCr or a CoCr alloy for the first intermediate layer 14 increases, the in-plane orientation of the c axis of the magnetic layer 16 improves. The Co content in CoCr or a CoCr alloy for the first intermediate layer 14 is more preferably greater than or equal to 90 atomic percent, since such a material provides a quite excellent in-plane orientation. When the first intermediate layer 14 is made of pure Co, it provides a further excellent in-plane orientation of the c axis of the magnetic layer 16.

The thickness of the first intermediate layer 14 is preferably greater than or equal to 0.5 nm. As described later in an example, when the first intermediate layer 14 having a thickness greater than or equal to 0.5 nm is provided, the ratio of perpendicular coercivity Hcp to in-plane coercivity Hci (Hcp/Hci, hereafter called “coercivity ratio”) decreases dramatically compared to the case where the first intermediate layer 14 is not provided. The decrease in the coercivity ratio means an improvement in the in-plane orientation of the c axis of the magnetic layer 16. When the first intermediate layer 14 is ferromagnetic and too thick, it generates noise and affects the S/N ratio of the magnetic recording medium 10. Therefore, the upper limit of the thickness of the first intermediate layer 14 is preferably less than or equal to 3.0 nm.

The second intermediate layer 15 is preferably made of Ru, Ti, Re, Zr, Hf, or Ru-X4 (X4 is selected from the group consisting of Ti, Re, Co, Zr, and Hf) each having a hexagonal closest packing crystalline structure. When the second intermediate layer 15 is made of Ru or Ru-X4, the second intermediate layer 15 may be a continuous film in which adjacent crystal grains are touching each other, or a granular structure in which crystal grains are isolated from each other by spaces in the in-plane direction. When the second intermediate layer 15 is a granular structure, magnetic grains in the magnetic layer 16 grow epitaxially on crystal grains made of Ru or Ru-X4, and, as a result, the magnetic grains are isolated from each other. Consequently, magnetic interaction between the magnetic grains is reduced, and the medium noise is reduced.

Also, the second intermediate layer 15 may have a structure composed of Ru or Ru-X4 and an oxide, nitride, or carbide (hereafter called “oxide or the like”) which does not dissolve Ru or Ru-X4 or dissolve in Ru or Ru-X4. In this case, crystal grains made of Ru or Ru-X4 grow in a direction perpendicular to the substrate surface, and form a structure in which each crystal grain is surrounded by non-dissolvable phases made of an oxide or the like. With this structure, magnetic grains in the magnetic layer 16 grow epitaxially on crystal grains made of Ru or Ru-X4, and, as a result, the magnetic grains are isolated from each other. Consequently, the medium noise is reduced because of the same reason described above. For the oxide or the like, an oxide such as SiO₂, Al₂O₃, or Ta₂O₅; a nitride such as Si₃N₄, AlN, TaN, ZrN, TiN, or Mg₃N₂; or a carbide such as SiC, TaC, ZrC, or TiC may be used. Since Ru and Ru-X4 are non-magnetic materials, they do not magnetically influence the magnetic layer 16 and contribute to reducing the medium noise further. The second intermediate layer 15 may be formed by sputtering a sputtering target made of Ru or Ru-X4 and a sputtering target made of an oxide or the like at the same time. A mixture of Ru or Ru-X4 and an oxide or the like may also be used as a sputtering target.

Depending on the conditions of depositing the second intermediate layer 15 or depending on the ratio of the content of Ru or Ru-X4 to the content of an oxide or the like in the second intermediate layer 15, almost no oxide or the like is formed between crystal grains but spaces are formed between them. Each space may be a vacuum or contain an inert gas or air.

Also, the thickness of the second intermediate layer 15 is preferably between 1 nm and 30 nm, and, in this range, thinner is better. Especially, when the first intermediate layer 14 is made of pure Co, as described later in an example, the thickness of the second intermediate layer 15 is preferably between 1 nm and 30 nm, and more preferably between 1 nm and 10 nm to provide a better coercivity ratio.

When the first intermediate layer 14 is made of CoCr or a CoCr alloy, the thickness of the second intermediate layer 15 is preferably between 5 nm and 30 nm to achieve a coercivity of the magnetic layer 16 of 3 kOe or more.

When the second intermediate layer 15 is made of Ru or Ru-X4 and has a granular structure or when the second intermediate layer 15 has a granular structure composed of Ru or Ru-X4 and an oxide or the like, it is preferable to form, as a base for the second intermediate layer 15, a polycrystalline intermediate continuous film made of Ru or Ru-X4 and having a structure in which adjacent crystal grains are touching each other. The crystal grains in the intermediate continuous film serve as growth nuclei for the crystal grains in the second intermediate layer 15 and improve the crystallinity at an early growth stage of the crystal grains, thereby further improving the crystallinity and crystal orientation of those crystal grains in the second intermediate layer 15.

The magnetic layer 16 is composed of many magnetic grains and non-dissolvable phases made of a non-magnetic material which surround each magnetic grain and isolate magnetic grains from each other in the in-plane direction. Each magnetic grain has a columnar structure and extends in a direction approximately perpendicular to the substrate surface. In other words, in the magnetic layer 16, each magnetic grain is surrounded by non-dissolvable phases and adjacent magnetic grains are isolated from each other by the non-dissolvable phases. Such a granular structure is self-organized by using sputtering or any other suitable method. Each magnetic grain is preferably composed of a single-crystalline region. However, a magnetic grain may be composed of multiple single-crystalline regions and may even contain crystal grain boundaries and crystal defects.

A magnetic grain is preferably made of a ferromagnetic material composed of CoPt, CoCrPt, or a CoCrPt alloy. As a CoCrPt alloy, CoCrPt-M (M includes at least one of the following elements: B, Mo, Nb, Ta, W, and Cu) may be used. The ferromagnetic material of the magnetic grain has a hexagonal closest packing crystalline structure and has an excellent lattice conformity with the second intermediate layer 15. As a result, magnetic grains are formed so that the c axis of each magnetic grain is aligned parallel to the c axis of the second intermediate layer 15. Therefore, the c axis of each magnetic grain is oriented in a direction parallel to the substrate surface.

When the ferromagnetic material for the magnetic grains is composed of the above mentioned CoCrPt-M, the Co content in the ferromagnetic material is preferably between 50 atomic percent and 80 atomic percent, the Pt content between 15 atomic percent and 30 atomic percent, the M concentration greater than O atomic percent and less than or equal to 20 atomic percent, and the Cr content the remaining atomic percent. Setting the Pt content in a range mentioned above (which is higher than that in a conventional longitudinal magnetic recording medium) increases the anisotropy field, thereby improving the in-plane coercivity and enabling increasing the recording density.

Each non-dissolvable phase is preferably made of a non-magnetic material which does not dissolve the ferromagnetic material of the magnetic grains or dissolve in the ferromagnetic material of the magnetic grains, or is made of a non-magnetic material which does not form a chemical compound with the ferromagnetic material of the magnetic grains. As the non-magnetic material, the above mentioned oxide or the like may be used. With the non-dissolvable phases, the magnetic grains are physically isolated from each other. As a result, magnetic interaction between the magnetic grains is reduced, the medium noise is reduced, and an excellent S/N ratio can be achieved.

The content of the non-dissolvable phases in the magnetic layer 16 is preferably between 5 atomic percent and 15 atomic percent, when the entire magnetic layer 16 is 100 atomic percent. If the content of the non-dissolvable phases is less than 5 atomic percent, magnetic grains become more likely to join, and it becomes difficult to sufficiently isolate magnetic grains from each other. On the other hand, a non-dissolvable phase content greater than 15 atomic percent means less magnetic grain content and causes the reproduction output to decrease. The non-dissolvable phase content can be obtained by a formula Y=My/(Mx+My)×100 (atomic percent). In the formula, Mx represents the number of atoms constituting the magnetic grains in the magnetic layer 16 and My represents the number of atoms constituting the non-dissolvable phases in the magnetic layer 16.

The thickness of the magnetic layer 16 is preferably between 5 nm and 30 nm, and more preferably between 10 nm and 20 nm to provide a better in-plane coercivity.

The protective film 18 has, for example, a thickness of between 0.5 nm and 15 nm, and is preferably made of a material composed of amorphous carbon, hydrogenated carbon, carbon nitride, or aluminum oxide. However, the material for the protective film 18 is not limited to the above mentioned materials.

The lubrication layer 19 has a thickness of between 0.5 nm and 5 nm, for example, and is preferably composed of a lubricant having a perfluoropolyether backbone chain. As the lubricant, a perfluoropolyether having an end group such as —OH or a piperonyl group may be used. The magnetic recording medium 10 may be configured with or without the lubrication layer 19 depending on the material of the protective film 18.

As described above, the first exemplary magnetic recording medium 10 is configured so that the in-plane orientation of the c axis of the magnetic layer 16 having a granular structure is improved by the underlayer 13 and the first intermediate layer 14; and the in-plane coercivity of the magnetic layer 16 is increased by the second intermediate layer 15. With this configuration, both the in-plane orientation and in-plane coercivity of the magnetic layer 16 can be improved while maintaining an excellent S/N ratio, which is a feature of the magnetic layer 16 having a granular structure. This configuration makes it possible to provide a magnetic recording medium 10 with an improved recording density.

A method of producing the first exemplary magnetic recording medium according to the first embodiment of the present invention is described below with reference to FIG. 1.

First, the surface of the substrate 11 is cleaned and dried, and then the substrate 11 is heated. In this heat treatment, the substrate 11 is heated by a heater or the like in a vacuum atmosphere to a specified temperature, for example, to 150° C. Before the heat treatment, a texture processing may be performed on the substrate surface. An example of such a texture processing is a mechanical texture processing in which, when the substrate 11 has a discoidal shape, multiple grooves are formed in a circumferential direction. Such a texture contributes to orienting the c axis of the magnetic layer 16 in a circumferential direction.

Next, with a sputtering apparatus and sputtering targets made of materials described above, the seed layer 12, the underlayer 13, the first intermediate layer 14, and the second intermediate layer 15 are formed in the order mentioned. More specifically, the sputtering is preferably performed by using a DC magnetron sputtering method in a deposition chamber with an Ar gas atmosphere at a pressure of 0.67 Pa. Also, it is preferable to evacuate the sputtering apparatus to a pressure of 10⁻⁷ Pa before sputtering and to supply a gas atmosphere, for example, an Ar gas atmosphere thereafter.

When Ru or Ru-X4 is used as a material for the second intermediate layer 15, the pressure in the deposition chamber is preferably greater than or equal to 0.67 Pa. Although there is no specific upper limit for the pressure, it is preferable to set the pressure less than or equal to 8 Pa, more preferably less than or equal to 4 Pa (30 mTorr), to prevent excessive surface roughness of the second intermediate layer 15. By setting the pressure as described above, spaces are formed between crystal grains, and a structure in which crystal grains are isolated from each other is formed. In this way, the second intermediate layer 15 is formed so that the crystal grains constituting the layer are isolated from each other. Instead of the DC magnetron sputtering method, the RF (AC) magnetron sputtering method may be used.

A granular structure composed of Ru or Ru-X4 and an oxide or the like may also be used for the second intermediate layer 15. Such a granular structure can be formed by using approximately the same method as that of forming the magnetic layer 16 described below.

Next, with the sputtering apparatus and a sputtering target made of ferromagnetic and non-magnetic materials described above, the magnetic layer 16 is formed on the second intermediate layer 15. More specifically, the magnetic layer 16 is deposited using a DC sputtering method, for example the DC magnetron sputtering method, with a sputtering target made of a mixture of ferromagnetic and non-magnetic materials, in an inert gas atmosphere at a pressure between 0.67 Pa and 8 Pa, by supplying an electric power of 500 W. Since a deposition apparatus for conventional magnetic recording media can be used for a DC sputtering method, equipment costs can be reduced. Also, since DC sputtering methods have higher sputtering rates than those of RF sputtering methods, it is possible to set a high deposition rate and to form a magnetic layer 16 with a desired thickness in a shorter time. In this sense, DC sputtering methods contribute to improving the efficiency of magnetic recording media production As described above, use of a DC sputtering method is preferable. However, an RF sputtering method may also be used to deposit the magnetic layer 16.

Also, the magnetic layer 16 may be formed by sputtering a sputtering target made of ferromagnetic material and a sputtering target made of non-magnetic material at the same time.

Next, the protective film 18 is formed on the magnetic layer 16 by using a sputtering method, a chemical vapor deposition (CVD) method, or a filtered cathodic arc (FCA) method.

Between the above described steps of forming the seed layer 12 and forming the protective film 18, the magnetic recording medium 10 is preferably kept in a vacuum or an inert gas atmosphere to maintain the cleanliness of the surface of each deposited layer.

Next, the lubrication layer 19 is formed on the protective film 18. The lubrication layer 19 is formed by applying a dilution of a lubricant in a solvent by using a dipping method or a spin coat method. The magnetic recording medium 10 according to the first embodiment of the present invention is produced as described above.

The above described production method provides the magnetic recording medium 10 having an excellent S/N ratio which is a feature of the magnetic layer 16 with a granular structure. The magnetic recording medium 10 also has an improved in-plane coercivity and in-plane orientation. In this production method, a DC sputtering method can be used to form the magnetic layer 16 having a granular structure. Therefore, layers from the seed layer 12 to the protective film 18 can be formed by using a DC sputtering method.

When Ru or Ru-X4 is used as the material for the second intermediate layer 15, setting the pressure in the deposition chamber at a certain value mentioned above causes crystal grains to be isolated from each other by spaces. As a result, the second intermediate layer 15 having a granular structure is formed.

The heat treatment for the substrate 11 is necessary only before the formation of the seed layer 12, and is not necessary before the formation of the magnetic layer 16. This eliminates the need for a vacuum chamber for the heat treatment and enables reducing the number of vacuum chambers in a continuous sputtering apparatus, thereby reducing equipment costs. Or, by providing another vacuum chamber for deposition in place of a vacuum chamber for the heat treatment, greater redundancy for the number of layers in a magnetic recording medium can be provided.

A second exemplary magnetic recording medium according to the first embodiment of the present invention is described below. The second exemplary magnetic recording medium is a variation of the first exemplary magnetic recording medium shown in FIG. 1.

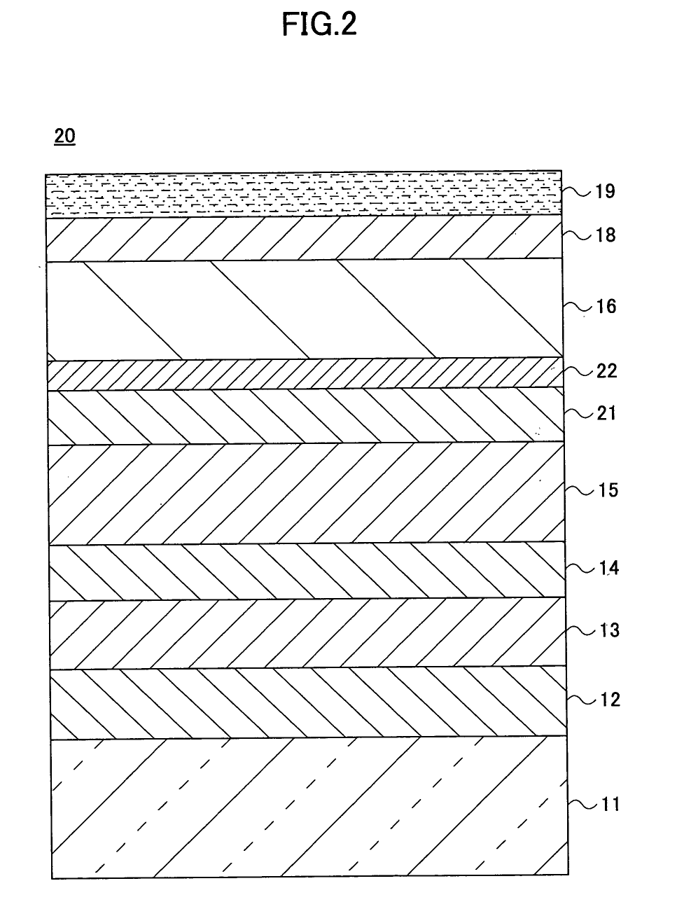

FIG. 2 is a cross-sectional view of a second exemplary magnetic recording medium according to the first embodiment of the present invention. The same reference numbers as those in FIG. 1 are assigned to the corresponding parts in FIG. 2, and descriptions of those parts are omitted.

As shown in FIG. 2, a second exemplary magnetic recording medium 20 has a structure in which a substrate 11, a seed layer 12, an underlayer 13, a first intermediate layer 14, a second intermediate layer 15, a first magnetic layer 21, a non-magnetic coupling layer 22, a second magnetic layer 16, a protective film 18, and a lubrication layer 19 are disposed from bottom to top in the order mentioned. In the magnetic recording medium 20, the magnetizations of the first magnetic layer 21 and the second magnetic layer 16 are antiferromagnetically coupled via the non-magnetic coupling layer 22. No external magnetic field is applied to those magnetizations and they have opposite orientations. The layered product made up of the first magnetic layer 21, the non-magnetic coupling layer 22, and the second magnetic layer 16 functions as a recording layer. Other layers are formed in the same manner as the corresponding layers in the first exemplary magnetic recording medium 10 shown in FIG. 1. The second magnetic layer 16 corresponds to the magnetic layer 16 in the first exemplary magnetic recording medium 10 shown in FIG. 1. Therefore, the same reference number “16” is assigned to the second magnetic layer 16.

The first magnetic layer 21 and the second magnetic layer 16 are composed of the same materials as those of the magnetic layer 16 in the first exemplary magnetic recording medium 10 shown in FIG. 1 and have a granular structure. Since the first magnetic layer 21 has a granular structure, the magnetic grains in the first magnetic layer 21 can grow epitaxially on the crystal grains composing the second intermediate layer 15. Then, on the magnetic grains in the first magnetic layer 21 and through the non-magnetic coupling layer 22, the magnetic grains in the second magnetic layer 16 grow epitaxially. In this way, the excellent in-plane orientation provided by the underlayer 13 and the first intermediate layer 14 carries over to the first magnetic layer 21 and the second magnetic layer 16.

The first magnetic layer 21 may be formed as an alloy magnetic layer having a Cr segregation structure. In this case, the first magnetic layer 21 is formed with a ferromagnetic material composed of CoCr or a CoCr alloy. As a CoCr alloy for the first magnetic layer 21, CoCrTa, CoCrPt, or CoCrPt-M (M is selected from the group consisting of B, Mo, Nb, Ta, W, and Cu) is preferably used. This first magnetic layer 21 forms a polycrystal where adjacent magnetic grains are touching each other. Since the magnetic grains in the first magnetic layer 21 grow epitaxially on the crystal grains of the second intermediate layer 15, the magnetic grains in the first magnetic layer 21 via the non-magnetic coupling layer 22 make it possible that the arrangement of magnetic grains in the second magnetic layer 16 are substantially the same as the arrangement of the crystal grains in the second intermediate layer 15. When the second intermediate layer 15 has a granular structure, it is acceptable that some of the grain boundaries between the magnetic grains in the first magnetic layer 21 are broken and spaces are formed because of isolated distribution of the crystal grains in the second intermediate layer 15.

In the first exemplary magnetic recording medium 10 shown in FIG. 1, the layered product made up of the underlayer 13, the first intermediate layer 14, and the second intermediate layer 15 provides an excellent in-plane orientation of the c axis of the magnetic layer 16. Also in the second exemplary magnetic recording medium 20, such layered product provides an excellent in-plane orientation of the c axis of the second magnetic layer 16 via the first magnetic layer 21 and the non-magnetic coupling layer 22.

The non-magnetic coupling layer 22 is preferably made of, for example, Ru, Rh, Ir, a Ru alloy, a Rh alloy, or a Ir alloy. Of those materials, Rh and Ir have a face-centered-cubic crystalline structure; and Ru has a hexagonal closest packing crystalline structure. The non-magnetic coupling layer 22 is preferably made of Ru or a Ru alloy, when the second magnetic layer 16 formed on the non-magnetic coupling layer 22 has a hexagonal closest packing crystalline structure. The Ru alloy is preferably Ru-X5 (X5 is selected from the group consisting of Co, Cr, Fe, Ni, and Mn). The thickness of the non-magnetic coupling layer 22 is preferably between 0.4 nm and 1.2 nm. Setting the thickness of the non-magnetic coupling layer 22 within this range enables the first magnetic layer 21 and the second magnetic layer 16 to be antiferromagnetically exchange-coupled via the non-magnetic coupling layer 22.

The thickness of the first magnetic layer 21 is preferably between 1 nm and 20 nm. The thickness of the first magnetic layer 21 is more preferably between 1.5 nm and 3.0 nm to achieve excellent recording/reproducing characteristics and to form a sufficiently large exchange-coupled magnetic field between the first magnetic layer 21 and the second magnetic layer 16. The thickness of the second magnetic layer 16 is preferably between 5 nm and 30 nm, and more preferably between 10 nm and 20 nm to provide a better in-plane coercivity. The thickness of the first magnetic layer 21 is preferably less than that of the second magnetic layer 16. Setting the thicknesses as described above contributes to maintaining reproduction output and preventing the thickness of the layered product made up of the first magnetic layer 21, the non-magnetic coupling layer 22, and the second magnetic layer 16 from increasing.

A method of producing the second exemplary magnetic recording medium 20 according to the first embodiment of the present invention is described below with reference to FIG. 2. The second exemplary magnetic recording medium 20 is produced by using approximately the same method as that of producing the first exemplary magnetic recording medium.

First, steps of cleaning the surface of the substrate 11 through forming the second intermediate layer 15 are performed by using the same method as that of producing the first exemplary magnetic recording medium.

Next, when the first magnetic layer 21 is an alloy magnetic layer described above, the first magnetic layer 21 is deposited in an inert gas atmosphere by using a DC sputtering method with a sputtering target made of a ferromagnetic material composed of Co, CoCr, or a CoCr alloy. In this case, before forming the first magnetic layer 21, the substrate 11 may be heated to 210° C. When the first magnetic layer 21 is a granular structure, the first magnetic layer 21 is formed by using the same method as that of forming the magnetic layer 16 in the first exemplary magnetic recording medium.

Next, the non-magnetic coupling layer 22 with a thickness of, for example, 0.7 nm is formed by using a DC sputtering method with a sputtering target made of, for example, Ru. Then, the second magnetic layer 16, the protective film 18, and the lubrication layer 19 are formed by using the same method as that of forming the corresponding layers in the first exemplary magnetic recording medium. The second exemplary magnetic recording medium 20 is produced as described above.

As described above, in the second exemplary magnetic recording medium 20, the first magnetic layer 21 and the second magnetic layer 16 are antiferromagnetically exchange-coupled. This configuration improves the thermal stability of the remanent magnetization and slows down the decrease of the amount of recorded magnetization. Therefore, the magnetic recording medium 20 provides similar advantages as those of the first exemplary magnetic recording medium 10 and has excellent long-term reliability.

A third exemplary magnetic recording medium according to the first embodiment of the present invention is described below. The third exemplary magnetic recording medium is a variation of the first exemplary magnetic recording medium shown in FIG. 1.

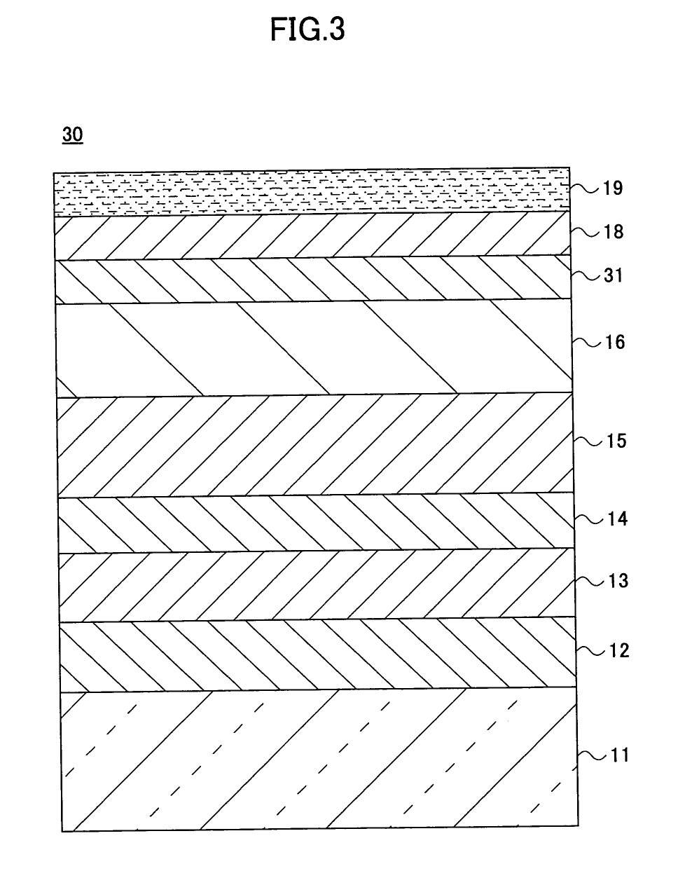

FIG. 3 is a cross-sectional view of the third exemplary magnetic recording medium according to the first embodiment of the present invention. The same reference numbers as those in previously described figures are assigned to the corresponding parts in FIG. 3, and descriptions of those parts are omitted.

As shown in FIG. 3, a third exemplary magnetic recording medium 30 has a structure in which a substrate 11, a seed layer 12, an underlayer 13, a first intermediate layer 14, a second intermediate layer 15, a magnetic layer 16, an alloy magnetic layer 31, a protective film 18, and a lubrication layer 19 are disposed from bottom to top in the order mentioned. The magnetic recording medium 30 is approximately the same as the first exemplary magnetic recording medium 10 shown in FIG. 1, except that an alloy magnetic layer 31 made of a metal ferromagnetic material is provided on the magnetic layer 16. The magnetic layer 16 and the alloy magnetic layer 31 are ferromagnetically coupled. They are approximately integrated and function as a recording layer.

The alloy magnetic layer 31 is preferably made of a CoCrPt alloy. As a CoCrPt alloy, CoCrPt-M (M includes at least one of the following elements: B, Mo, Nb, Ta, W, and Cu) may be used. The alloy magnetic layer 31 is a polycrystal where adjacent magnetic (crystal) grains are touching each other. This configuration enables adequate combination and use of the magnetic anisotropy and low-noise structure provided by the magnetic layer 16 and the exchange coupling between grains in the alloy magnetic layer 31, thereby lowering the switching magnetic field intensity for recording while maintaining the thermal stability of the remanent magnetization of the recording layer made up of the magnetic layer 16 and the alloy magnetic layer 31. This in turn makes it possible to record with a smaller recording magnetic field intensity (improvement in recordability), improves the overwrite characteristics, and improves the S/N ratio.

The magnetic layer 16 has a granular structure composed of magnetic grains and non-dissolvable phases. Because of the difference in growth rate between the magnetic grains and the non-dissolvable phases, minute concavities and convexities tend to be formed on the surface of the magnetic layer 16, resulting in deterioration of the surface condition of the magnetic layer 16. However, the deterioration of the surface condition can be avoided by depositing the alloy magnetic layer 31 on the surface of the magnetic layer 16.

The magnetic grains in the alloy magnetic layer 31 have a hexagonal closest packing crystalline structure. This structure provides the alloy magnetic layer 31 with an excellent lattice conformity with the magnetic grains in the magnetic layer 16 and improves the crystallinity and crystal orientation of the alloy magnetic layer 31, thereby improving the recording/reproducing characteristics.

The saturation magnetic flux density of the alloy magnetic layer 31 is preferably set greater than that of the magnetic layer 16. This setting contributes to decreasing the overall thickness of the recording layer composed of the magnetic layer 16 and the alloy magnetic layer 31 while maintaining the reproduction output, thereby improving the recording performance such as the overwrite characteristics. The thickness of the alloy magnetic layer 31 is preferably greater than or equal to 1 nm to decrease the demagnetizing field intensity and to prevent the surface roughness. The thickness of the alloy magnetic layer 31 is more preferably less than or equal to 10 nm to decrease the medium noise. Further, the thickness of the alloy magnetic layer 31 is preferably between 3 nm and 5 nm to more effectively decrease both the demagnetizing field intensity and the medium noise.

As described above, the third exemplary magnetic recording medium 30 provides similar advantages as those of the first exemplary magnetic recording medium 10. In addition, having the alloy magnetic layer 31 on the magnetic layer 16 with a granular structure contributes to lowering the switching magnetic field intensity for recording while maintaining the thermal stability of the remanent magnetization of the recording layer made up of the magnetic layer 16 and the alloy magnetic layer 31, thereby improving the recordability and the S/N ratio.

A fourth exemplary magnetic recording medium according to the first embodiment of the present invention is described below. The fourth exemplary magnetic recording medium has a configuration where the alloy magnetic layer 31 in the third exemplary magnetic recording medium 30 shown in FIG. 3 is added to the second exemplary magnetic recording medium 20 shown in FIG. 2.

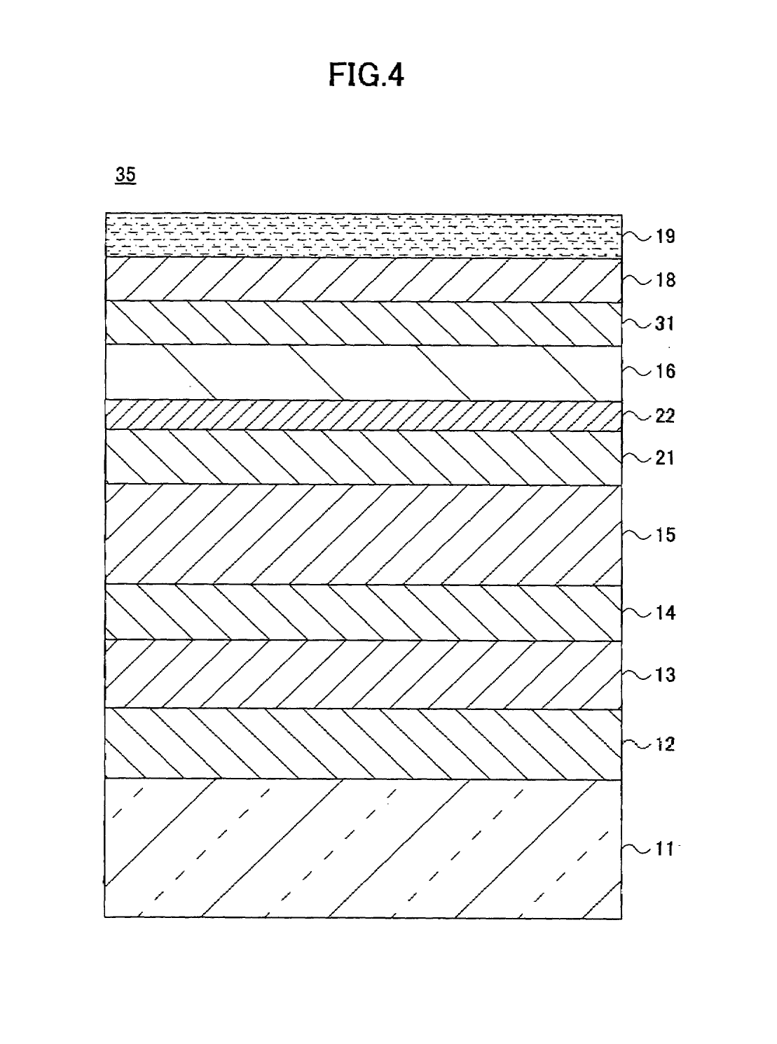

FIG. 4 is a cross-sectional view of a fourth exemplary magnetic recording medium according to the first embodiment of the present invention. The same reference numbers as those in previously described figures are assigned to the corresponding parts in FIG. 4, and descriptions of those parts are omitted.

As shown in FIG. 4, a fourth exemplary magnetic recording medium 35 has a structure in which a substrate 11, a seed layer 12, an underlayer 13, a first intermediate layer 14, a second intermediate layer 15, a first magnetic layer 21, a non-magnetic coupling layer 22, a second magnetic layer 16, an alloy magnetic layer 31, a protective film 18, and a lubrication layer 19 are disposed from bottom to top in the order mentioned. The magnetic recording medium 35 is approximately the same as the second exemplary magnetic recording medium 20 shown in FIG. 2, except that the alloy magnetic layer 31 made of a metal ferromagnetic material is provided on the second magnetic layer 16. The magnetic layer 16 and the alloy magnetic layer 31 are ferromagnetically coupled. They are approximately integrated and function as a recording layer. The alloy magnetic layer 31 is preferably made of the same material and preferably has the same thickness as in the third exemplary magnetic recording material. Also, the function of the alloy magnetic layer 31 is the same as in the third exemplary magnetic recording material.

Therefore, the fourth exemplary magnetic recording medium 35 provides similar advantages as those of the second exemplary magnetic recording medium 20. In addition, having the alloy magnetic layer 31 on the magnetic layer 16 with a granular structure contributes to lowering the switching magnetic field intensity for recording while maintaining the thermal stability of the remanent magnetization of the recording layer made up of the first magnetic layer 21, the non-magnetic coupling layer 22, the second magnetic layer 16, and the alloy magnetic layer 31, thereby improving the recordability and the S/N ratio.

Examples 1 through 9 according to the first embodiment of the present invention are described below. The configuration of each magnetic recording medium in examples 1 through 9 is the same as that of the first exemplary magnetic recording medium described above.

### EXAMPLE 1 AND COMPARATIVE EXAMPLE 1

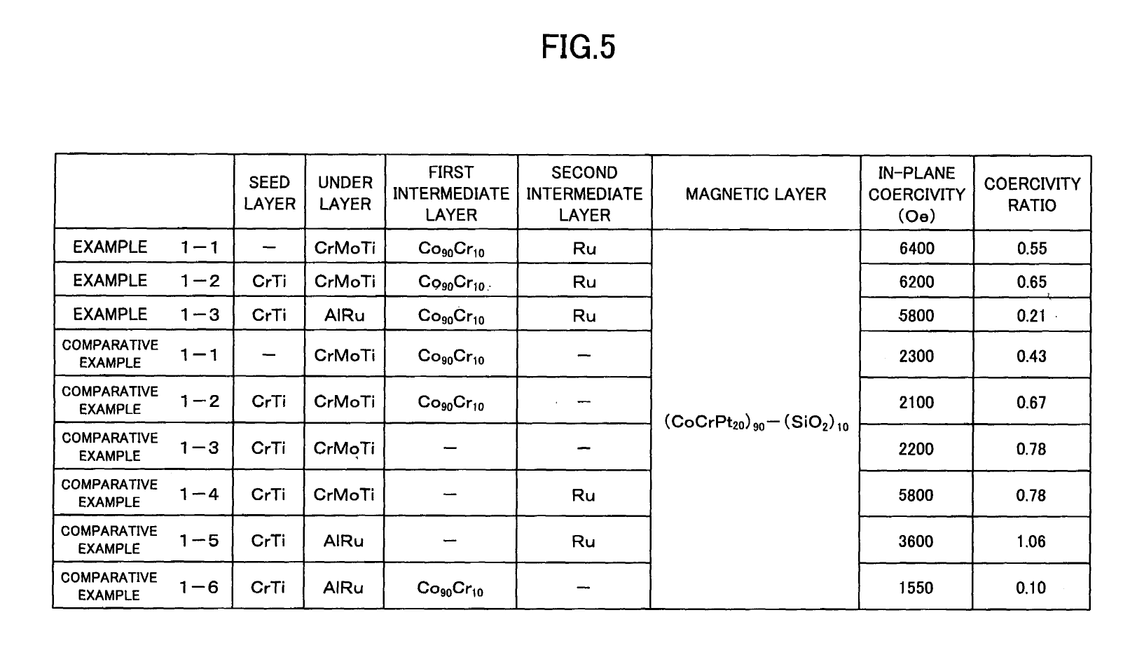

FIG. 5 is a table showing exemplary layer configurations and magnetic properties of magnetic disks in example 1 and comparative example 1. In FIG. 5, the composition of each layer is expressed in atomic percent. In the composition (CoCrPt₂₀)₉₀—(SiO₂)₁₀ of the sputtering target material for the magnetic layer, (CoCrPt₂₀)₉₀ is the composition of the ferromagnetic material (the Pt content in the ferromagnetic material is 20 atomic percent, where the total atomic percent of the ferromagnetic material is 100); and (SiO₂)₁₀ is a chemical formula for the composition of the non-magnetic material. CoCrPt₂₀ constitutes 90 atomic percent and SiO₂ constitutes 10 atomic percent of the sputtering target material. In FIG. 5, the protective film is omitted.

The in-plane coercivity is obtained by measuring the Kerr rotation angle by applying a magnetic field for measurement in a plane parallel to the substrate surface in a circumferential direction. The coercivity ratio is the ratio of perpendicular coercivity Hcp to in-plane coercivity Hci (Hcp/Hci). A lower coercivity ratio value indicates a better in-plane orientation. The perpendicular coercivity Hcp is obtained by measuring the Kerr rotation angle by applying a magnetic field for measurement in a direction perpendicular to the substrate surface.

The magnetic disks in example 1 (examples 1-1 through 1-3) and comparative example 1 (comparative examples 1-1 through 1-6) shown in FIG. 5 are produced as described below.

First, a glass substrate having a mechanical texture on its surface is cleaned. The substrate is heated to 150° C. Then, by using an opposed DC magnetron sputtering apparatus, a seed layer, an underlayer, a first intermediate layer, a second intermediate layer, a magnetic layer, and a protective film (carbon film) are formed. An argon gas is supplied to the deposition chamber of the DC magnetron sputtering apparatus. Sputtering targets made of materials shown in FIG. 5 are sputtered in the argon gas atmosphere at a pressure of 0.67 Pa except for the deposition of the Ru film by using the DC magnetron sputtering method. In the deposition of the Ru film, the pressure is set at 4 Pa. In the table shown in FIG. 5, “˜” indicates that the corresponding layer is not formed. The material in each cell for each layer is expressed by its composition and the content of each element is expressed in atomic percent.

The thickness of CrTi film is 25 nm, AlRu film is 20 nm, CrMoTi film is 6 nm, CO₉₀Cr₁₀ film is 1.5 nm, Ru film is 30 nm, (CoCrPt₂₀)₉₀—(SiO₂)₁₀ film is 15 nm, and carbon film is 4.5 nm.

Example 1-1 has a configuration where a Ru film as the second intermediate layer is added to the configuration of comparative example 1-1.

Example 1-1 has an in-plane coercivity about three times larger than that of comparative example 1-1 and a coercivity ratio approximately the same as that of comparative example 1-1. This result indicates that forming a Ru film as the second intermediate layer increases the in-plane coercivity while maintaining the in-plane orientation.

Example 1-2 has a configuration where a Ru film as the second intermediate layer is added to the configuration of comparative example 1-2. Example 1-2 has an in-plane coercivity about three times larger than that of comparative example 1-2 and a coercivity ratio approximately the same as that of comparative example 1-2. This result is the same as that of example 1-1 and indicates that forming a Ru film as the second intermediate layer increases the in-plane coercivity while maintaining the in-plane orientation.

Comparative example 1-3 has a configuration where a CO₉₀Cr₁₀ film is removed from comparative example 1-2. However, the in-plane coercivity and the coercivity ratio of comparative example 1-3 is approximately the same as those of comparative example 1-2. This result indicates that a Ru film as the second intermediate layer is necessary to achieve a high coercivity ratio.

Example 1-2 has a configuration where a CO₉₀Cr₁₀ film as the first intermediate layer is added to the configuration of comparative example 1-4. Example 1-2 has a larger in-plane coercivity and a lower coercivity ratio than those of comparative example 1-4, and accordingly has a better in-plane orientation. This result indicates that the CO₉₀Cr₁₀ film as the first intermediate layer improves the crystallinity of the Ru film and the crystal orientation of the (0001) plane, and consequently improves the crystallinity of magnetic grains and in-plane orientation of the c axis in the magnetic layer.

Example 1-3 has a configuration where a AlRu film is formed as the underlayer in place of the CrMoTi film in example 1-2. Example 1-3 has a coercivity ratio about one third as large as that of example 1-2 and has a quite excellent in-plane orientation. On the other hand, the in-plane coercivity of example 1-3 is approximately the same as that of example 1-2. This result indicates that forming an AlRu film as the underlayer greatly increases the in-plane orientation while maintaining the in-plane coercivity.

Example 1-3 has a configuration where a CO₉₀Cr₁₀ film as the first intermediate layer is added to the configuration of comparative example 1-5. Example 1-3 has a larger in-plane coercivity and a better in-plane orientation than those of comparative example 1-5. This result indicates that the CO₉₀Cr₁₀ film as the first intermediate layer improves the crystallinity and crystal orientation of the (0001) plane of the Ru film, and consequently improves the crystallinity of magnetic grains and in-plane orientation of the c axis in the magnetic layer.

Example 1-3 has a configuration where a Ru film as the second intermediate layer is added to the configuration of comparative example 1-6. Example 1-3 has an in-plane coercivity about four times larger than that of comparative example 1-6 and an approximately the same coercivity ratio as that of comparative example 1-6. This result indicates that forming a Ru film as the second intermediate layer increases the in-plane coercivity while maintaining the in-plane orientation. Although the materials for underlayers in examples 1-3 and 1-2 are different, the effects of the Ru films as the second intermediate layers in these examples are the same.

### EXAMPLE 2 AND COMPARATIVE EXAMPLE 2

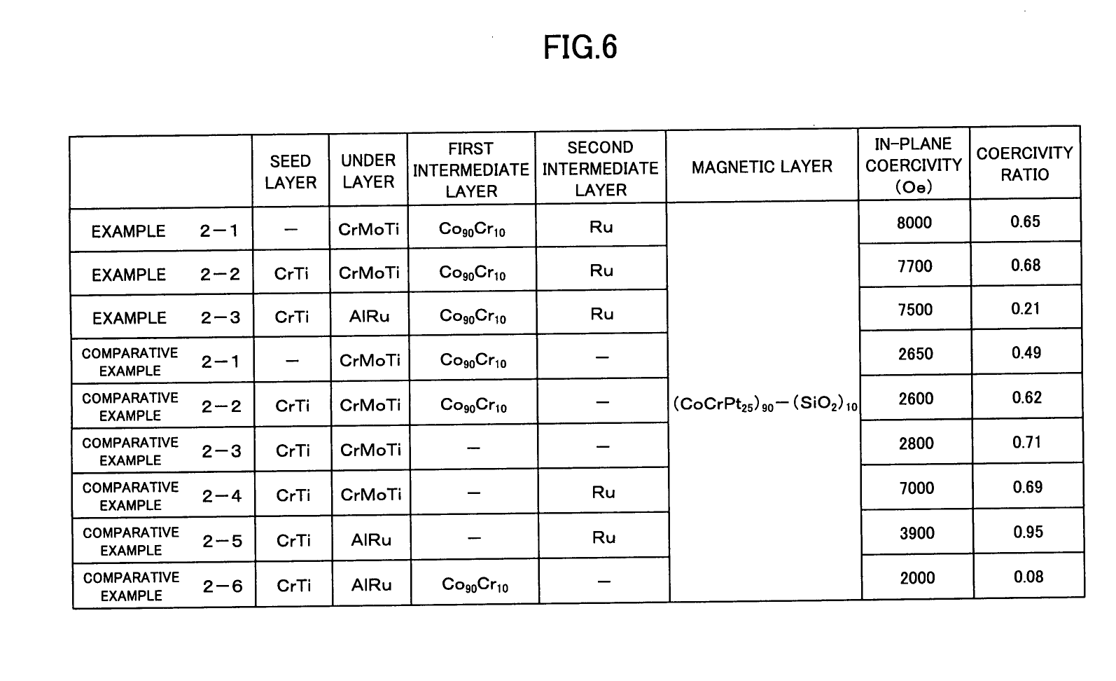

FIG. 6 is a table showing exemplary layer configurations and magnetic properties of magnetic disks in example 2 and comparative example 2.

As shown in FIG. 6, magnetic disks in example 2 and comparative example 2 use the same materials and layer configurations as those in example 1 and comparative example 2, except that (CoCrPt₂₅)₉₀—(SiO₂)₁₀ is used as the composition of the sputtering target material for the magnetic layer. The layer configurations of examples 2-1 through 2-3 and comparative examples 2-1 through 2-6 are the same as those of examples 1-1 through 1-3 and comparative examples 1-1 through 1-6, except the material for the magnetic layer. Magnetic disks in example 2 have advantages similar to those in example 1 over magnetic disks in comparative example 2.

### EXAMPLES 3 AND 4

In examples 3 and 4, magnetic disks having magnetic layer thicknesses between 10 nm and 30 nm are produced and their in-plane coercivities and coercivity ratios are measured in a same manner as in example 1.

Magnetic disks in example 3 have a layer configuration where a substrate, a seed layer (CrTi film: 25 nm), an underlayer (AlRu film: 20 nm and CrMoTi film: 6 nm), a first intermediate layer (CO₉₀Cr₁₀ film: 1.5 nm), a second intermediate layer. (Ru film: 30 nm), a magnetic layer ((CoCrPt₂₀)₉₀—(SiO₂)₁₀ film: 15 nm), and a protective film (carbon film: 4.5 nm) are disposed from the bottom to the top in the order mentioned. Magnetic disks in example 4 have the same configuration as that in example 3, except that the material for the magnetic layer is (CoCrPt₂₅)₉₀—(SiO₂)₁₀. The deposition conditions in examples 3 and 4 are the same as those in example 1.

In the above description, figures in brackets (25 nm, for example) show thicknesses of corresponding layers. Thicknesses are expressed in the same manner in the descriptions below.

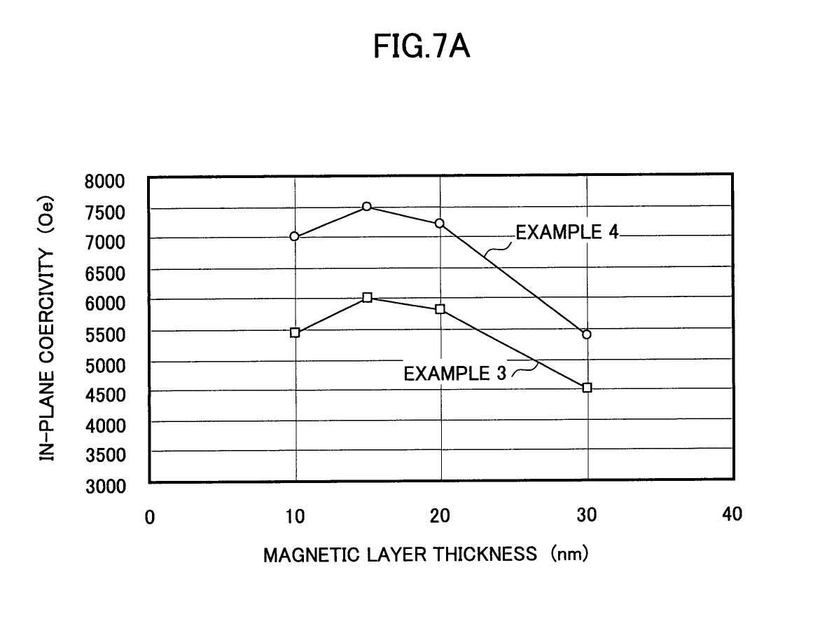

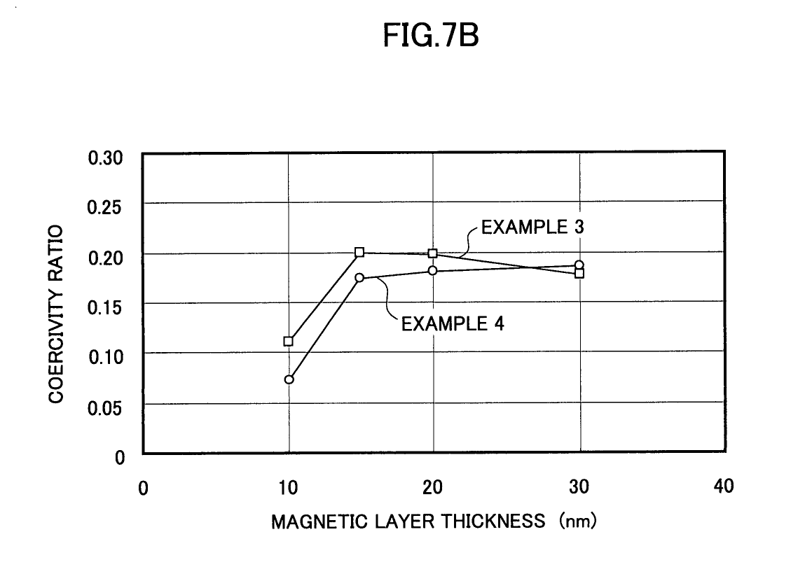

FIG. 7A is a graph showing a relationship between in-plane coercivities and magnetic layer thicknesses of magnetic disks in examples 3 and 4; FIG. 7B is a graph showing a relationship between coercivity ratios and magnetic layer thicknesses of magnetic disks in examples 3 and 4.

As shown in FIGS. 7A and 7B, magnetic disks in examples 3 and 4 show the highest coercivities at a magnetic layer thickness of around 15 nm. This result indicates that the magnetic layer thickness is preferably between 10 nm and 20 nm to achieve a high coercivity. Also, the larger the thickness of the magnetic layer, the larger the magnetic grain diameter may become, resulting in an increased medium noise. Therefore, also in this respect, the magnetic layer thickness is preferably between 10 nm and 20 nm.

Although the coercivity ratios are sufficiently low with the magnetic layer thicknesses between 10 nm and 30 nm, a smaller magnetic layer thickness results in a better coercivity ratio. Taking these results into consideration, the magnetic layer thickness is preferably between 10 nm and 20 nm to achieve both an excellent in-plane coercivity and coercivity ratio at the same time.

### EXAMPLE 5

A magnetic disk in example 5 has the same layer configuration as that in example 3, except that the first intermediate layer is a pure Co film. The thickness of the pure Co film as the first intermediate layer is incremented by 0.5 nm within a range between 0.5 nm and 2.0 nm. The deposition conditions in example 5 are the same as those in example 1.

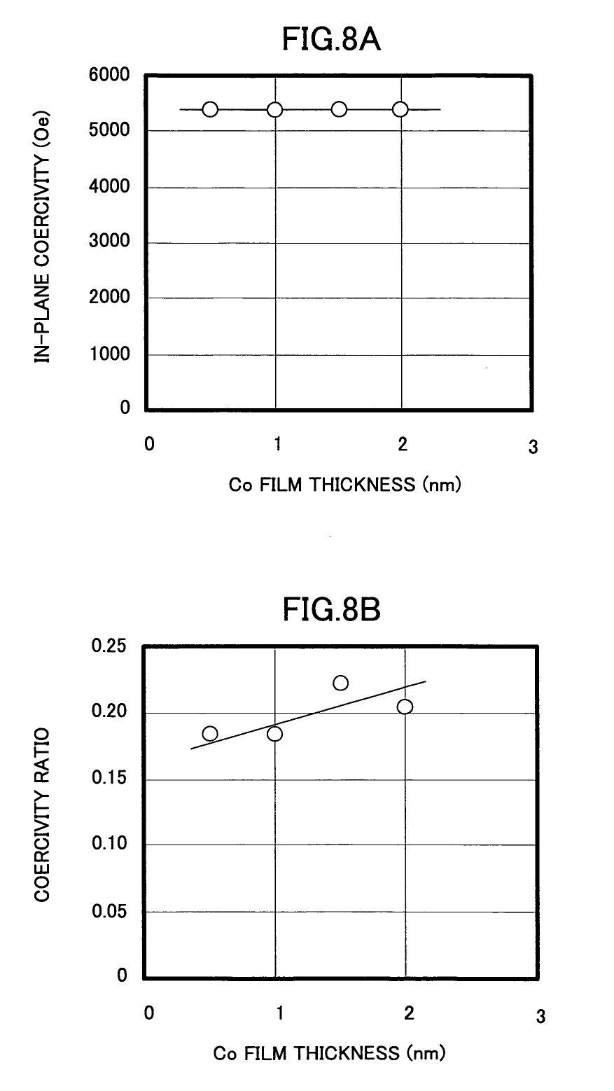

FIG. 8A is a graph showing a relationship between in-plane coercivities and Co film thicknesses of the magnetic disk in example 5; FIG. 8B is a graph showing a relationship between coercivity ratios and Co film thicknesses of the magnetic disk in example 5.

As shown in FIG. 8A and FIG. 8B, Co film thicknesses of the first intermediate layer between 0.5 nm and 2.0 nm provide excellent and approximately constant in-plane coercivities and coercivity ratios. A Co film thickness of greater than or equal to 0.5 nm provides a sufficiently high in-plane coercivity and an excellent in-plane orientation. Also, even a Co film thickness of greater than 2 nm may provide a sufficiently high in-plane coercivity and an excellent in-plane orientation.

### EXAMPLE 6

A magnetic disk in example 6 has the same layer configuration as that in example 5. In example 6, the pure Co film as the first intermediate layer has a thickness of 1.5 nm, and the thickness of the Ru film as the second intermediate layer is incremented within a range between 1 nm and 30 nm. Also, a magnetic disk in comparative example 3 for comparison with example 6 has the same layer configuration as that in example 6, except that the Ru film is not provided in comparative example 3.

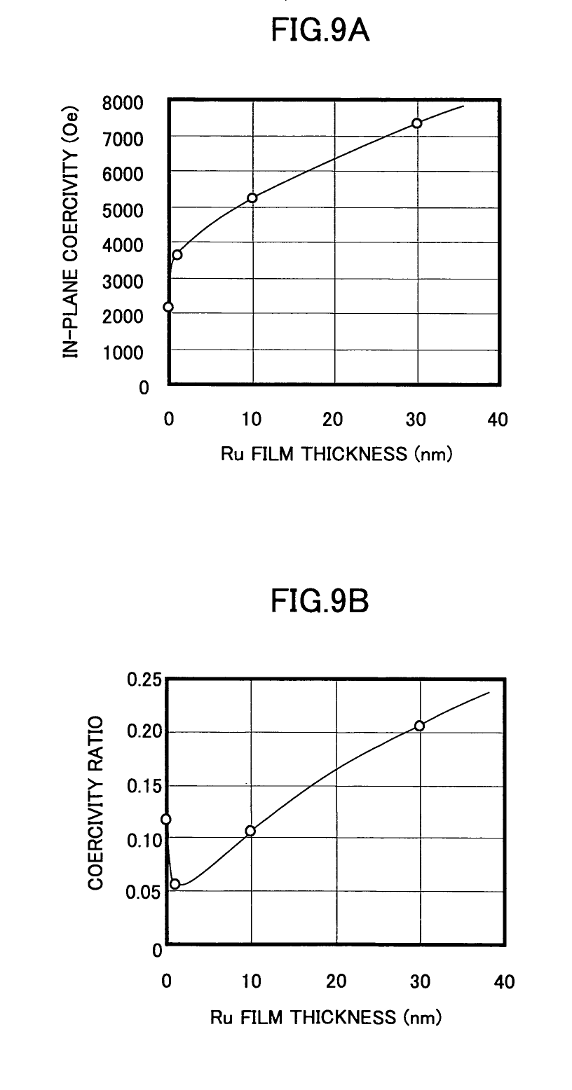

FIG. 9A is a graph showing a relationship between in-plane coercivities and Ru film thicknesses of the magnetic disk in example 6; FIG. 9B is a graph showing a relationship between coercivity ratios and Ru film thicknesses of the magnetic disk in example 6. The in-plane coercivity and coercivity ratio of the magnetic disk in comparative example 3 are shown in FIG. 9A and FIG. 9B at a Ru film thickness of 0 nm, respectively.

As shown in FIG. 9A, Ru film thicknesses between 1 nm and 30 nm provide higher in-plane coercivities compared with a case where the Ru film is not provided. Especially, at a Ru film thickness of 1 nm, the in-plane coercivity is much higher than that of a magnetic disk in which no Ru film is provided.

As shown in FIG. 9B, the Ru film thicknesses between 1 nm and 30 nm provide sufficient coercivity ratios. A smaller Ru film thickness, especially between 1 nm and 10 nm, provides a better coercivity ratio Therefore, according to the results in example 6, the thickness of the Ru film is preferably between 1 nm and 30 nm, and more preferably between 1 nm and 10 nm.

### EXAMPLE 7

A magnetic disk in example 7 has a CO₉₀Cr₁₀ film as the first intermediate layer with a thickness incremented between 0.5 nm and 3 nm. Also, a magnetic disk in comparative example 4 for comparison with example 7 has the same layer configuration as that in example 7, except that the CO₉₀Cr₁₀ film is not provided in comparative example 4.

The magnetic disk in example 7 has the same configuration as that in example 3, except that the material for the magnetic layer is a (CoCrPt₂₅)₉₀—(SiO₂)₁₀ film (15 nm).

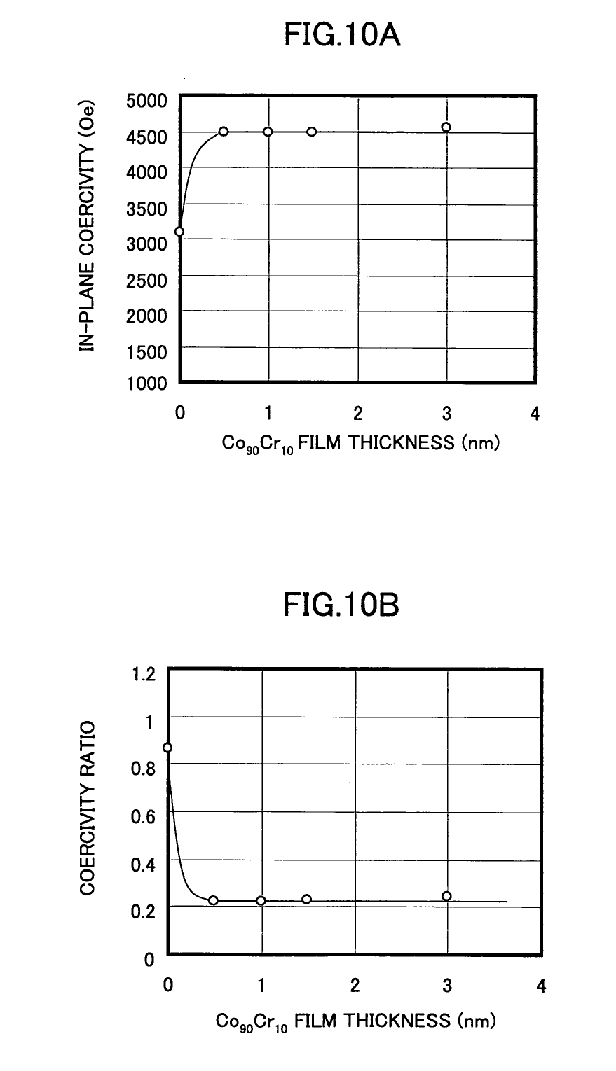

FIG. 10A is a graph showing a relationship between in-plane coercivities and CO₉₀Cr₁₀ film thicknesses of the magnetic disk in example 7; FIG. 10B is a graph showing a relationship between coercivity ratios and CO₉₀Cr₁₀ film thicknesses of the magnetic disk in example 7. The in-plane coercivity and coercivity ratio of the magnetic disk in comparative example 4 are shown in FIG. 10A and FIG. 10B at a CO₉₀Cr₁₀ film thickness of 0 nm, respectively.

As shown in FIG. 10A and FIG. 10B, CO₉₀Cr₁₀ film thicknesses of the first intermediate layer between 0.5 nm and 3.0 nm provide excellent and approximately constant in-plane coercivities and coercivity ratios. This result indicates that a CO₉₀Cr₁₀ film thickness of greater than or equal to 0.5 nm provides a sufficiently high in-plane coercivity and an excellent in-plane orientation. Also, even a CO₉₀Cr₁₀ film thickness of greater than 3 nm may provide a sufficiently high in-plane coercivity and an excellent in-plane orientation.

### EXAMPLE 8 AND COMPARATIVE EXAMPLE 9

Magnetic disks in examples 8 and 9 have the same configuration as that in example 3, except that different pressures are used in depositing the Ru films as the second intermediate layers. In example 8, the pressure is set at 0.67 Pa; in example 9, the pressure is set at 4 Pa. Other deposition conditions in examples 8 and 9 are the same as those in example 1.

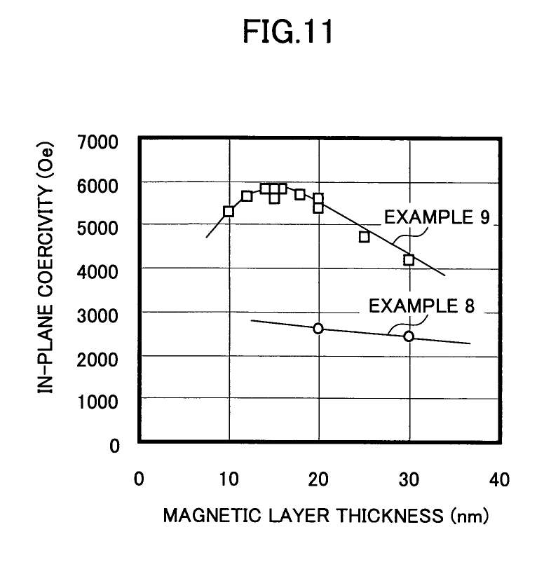

FIG. 11 is a graph showing a relationship between in-plane coercivities and magnetic layer thicknesses of magnetic disks in examples 8 and 9.

As shown in FIG. 11, within a range of magnetic layer thicknesses between 10 nm and 30 nm, the magnetic disk in example 9 has much larger in-plane coercivities than those of the magnetic disk in example 8. This result indicates that, in depositing the Ru film, a pressure of 4 Pa is more preferable than a pressure of 0.67 Pa to increase the in-plane coercivity of a magnetic recording medium.

Although a higher pressure provides a higher in-plane coercivity of a magnetic recording medium, the pressure in depositing the Ru film is preferably between 0.655 Pa and 8 Pa, and more preferably between 4 Pa and 8 Pa to achieve a high in-plane coercivity.

### 2. Second Embodiment

The second embodiment relates to a magnetic storage apparatus having a magnetic recording medium according to the first embodiment.

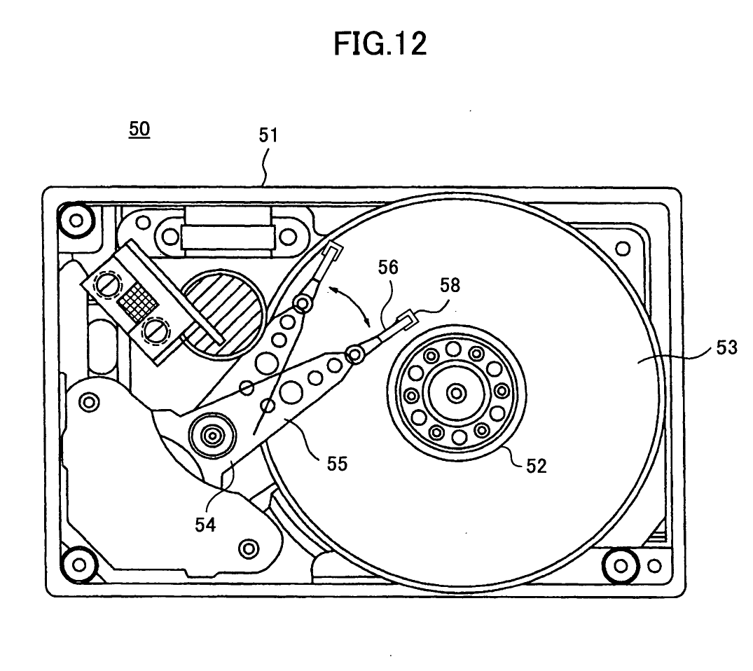

FIG. 12 is a drawing showing a portion of an exemplary magnetic storage apparatus according to a second embodiment of the present invention. As shown in FIG. 12, a magnetic storage apparatus 50 includes a housing 51. In the housing 51, the magnetic storage apparatus 50 includes a hub 52 which is driven by a spindle (not shown), a magnetic recording medium 53 which is rotatably fixed to the hub 52, an actuator unit 54, an arm 55 and a suspension 56 which are fixed to the actuator unit 54 and movable in a radial direction of the magnetic recording medium 53, and a magnetic head 58 which is supported by the suspension 56. The magnetic head 58 is a combination head including a reproducing head such as a magnetoresistive (MR) element, a giant magnetoresistive (GMR) element, or a tunneling magnetoresistive (TMR) element and an induction-type recording head.

The magnetic recording medium 53 is any one of the first through fourth exemplary magnetic recording media according to the first embodiment of the present invention. The magnetic recording medium 53 has an excellent S/N ratio and an excellent in-plane coercivity and in-plane orientation of the recording layer, thereby enabling production of the magnetic storage apparatus 50 having a high recording density.

The basic configuration of the magnetic storage apparatus 50 is not limited to the configuration shown in FIG. 12. The configuration of the magnetic head 58 is not limited to the configuration mentioned above and a known magnetic head may be used in the magnetic storage apparatus 50.

The present invention is not limited to the specifically disclosed embodiments, and variations and modifications may be made without departing from the scope of the present invention.

For example, a magnetic tape may be used as a magnetic recording medium in place of the magnetic disk in the second embodiment of the present invention. For the magnetic tape, a tap-shaped substrate, for example a tape-shaped plastic film made of PET, PEN, or polyimide, may be used instead of a discoidal substrate.

What is claimed is:

1. A magnetic recording medium, comprising:
a substrate;
an underlayer positioned on the substrate and made of a material having a body-centered-cubic crystalline structure or a B2 crystalline structure;
a first intermediate layer positioned on the underlayer and having a hexagonal closest packing crystalline structure, and being made of Co or a Co alloy;
a second intermediate layer positioned on the first intermediate layer and having a hexagonal closest packing crystalline structure, and being made of a material selected from the group consisting of Ru, Ti, Re, Zr, Hf, and a Ru alloy; and
a magnetic layer positioned on the second intermediate layer and including a plurality of magnetic grains each having a hexagonal closest packing crystalline structure and an axis of easy magnetization oriented in a direction substantially parallel to a surface of the substrate, wherein the magnetic grains are isolated from each other.

2. The magnetic recording medium as claimed in claim 1, wherein the magnetic grains in the magnetic layer are isolated from each other in a direction parallel to the substrate surface by spaces or a non-magnetic material.

3. The magnetic recording medium as claimed in claim 1, wherein the magnetic layer includes non-dissolvable phases which surround each of the magnetic grains and are made of a non-magnetic material composed of an oxide, a nitride, or a carbide.

4. The magnetic recording medium as claimed in claim 1, wherein the magnetic grains in the magnetic layer are made of a ferromagnetic material selected from the group consisting of CoPt, CoCrPt, or a CoCrPt alloy.

5. The magnetic recording medium as claimed in claim 1, wherein the underlayer being made of a material having a body-centered-cubic crystalline structure is composed of Cr or a Cr alloy.

6. The magnetic recording medium as claimed in claim 1, wherein the underlayer being made of a material having a B2 crystalline structure is selected from the group consisting of AlCo, AlMn, AlRe, AlRu, AgMg, CuBe, CuZn, CoFe, CoHf, CoTi, CoZr, FeAl, FeTi, NiAl, NiFe, NiTi, AlRuNi, and Al₂FeMn₂.

7. The magnetic recording medium as claimed in claim 1, wherein the first intermediate layer is made of Co, or CoCr or a CoCr alloy in each of which Co content is greater than or equal to 63 atomic percent and less than 100 atomic percent.

8. The magnetic recording medium as claimed in claim 1, wherein the second intermediate layer includes crystal grains made of Ru or Ru-X4, where X4 is selected from the group consisting of Ti, Re, Co, Zr, and Hf, and the crystal grains are isolated from each other.

9. The magnetic recording medium as claimed in claim 8, wherein the second intermediate layer includes a non-magnetic material which surrounds each crystal grain and is composed of an oxide, a nitride, or a carbide.

10. The magnetic recording medium as claimed in claim 8, further comprising:
an intermediate continuous film positioned directly under the second intermediate layer and including crystal grains made of Ru or Ru-X4, where X4 is selected from the group consisting of Ti, Re, Co, Zr, and Hf, wherein adjacent crystal grains are touching each other.

11. The magnetic recording medium as claimed in claim 1, further comprising:
a CoCrPt alloy magnetic layer positioned on said magnetic layer and made of a CoCrPt alloy.

12. The magnetic recording medium as claimed in claim 1, wherein the magnetic layer is a second magnetic layer and the magnetic recording medium further comprises:
a first magnetic layer on the second intermediate layer; and
a non-magnetic coupling layer between the first magnetic layer and the second magnetic layer, wherein the first magnetic layer and the second magnetic layer are antiferromagnetically exchange-coupled via the non-magnetic coupling layer.

13. The magnetic recording medium as claimed in claim 12, wherein the first magnetic layer includes a plurality of magnetic grains each having a hexagonal closest packing crystalline structure and an axis of easy magnetization oriented in a direction substantially parallel to the substrate surface; and non-dissolvable phases which surround each of the magnetic grains and made of a non-magnetic material composed of an oxide, a nitride, or a carbide.

14. The magnetic recording medium as claimed in claim 12, further comprising:
a CoCrPt alloy magnetic layer positioned on the second magnetic layer and made of a CoCrPt alloy.

15. The magnetic recording medium as claimed in claim 1, further comprising:
a seed layer positioned between the substrate and the underlayer and made of a non-magnetic alloy material in an amorphous state.

16. A method of producing a magnetic recording medium, comprising:
an underlayer forming step of forming on a substrate an underlayer by depositing a material having a body-centered-cubic crystalline structure or a B2 crystalline structure;
a first intermediate layer forming step of forming on the underlayer a first intermediate layer having a hexagonal closest packing crystalline structure by depositing a material composed of Co or a Co alloy;
a second intermediate layer forming step of forming on the first intermediate layer a second intermediate layer having a hexagonal closest packing crystalline structure by depositing a material selected from the group consisting of Ru, Ti, Re, Zr, Hf, and a Ru alloy; and
a magnetic layer forming step of forming on the second intermediate layer a magnetic layer by sputtering simultaneously a ferromagnetic material and a non-magnetic material which does not dissolve the ferromagnetic material or dissolve in the ferromagnetic material and is composed of an oxide, a nitride, or a carbide.

17. The method of producing a magnetic recording medium as claimed in claim 16, wherein a DC sputtering method is used in the magnetic layer forming step.

18. The method of producing a magnetic recording medium as claimed in claim 16, wherein, in the second intermediate layer forming step, a pressure between 0.67 Pa and 8 Pa is used and a material composed of Ru or a Ru alloy is sputtered.

19. The method of producing a magnetic recording medium as claimed in claim 16, wherein, in the second intermediate layer forming step, a material made of Ru or Ru-X4, where X4 is selected from the group consisting of Ti, Re, Co, Zr, and Hf, and a non-magnetic material composed of an oxide, a nitride, or a carbide are sputtered simultaneously.

20. A magnetic storage apparatus, comprising:
a magnetic recording medium as claimed in claim 1; and
a record reproducing unit including a magnetic head disposed with respect to the medium.
